(19) United States
(12) Patent Application Publication
(10) Pub. No.: US 2008/0160699 A1
(43) Pub. Date: Jul. 3, 2008

(54) Method for Fabricating Semiconductor Device Having Bulb-Type Recessed Channel

(75) Inventors: Min Yong Lee, Seoul (KR); Yong Seok Eun, Seongnam-si (KR); Dong Su Park, Icheon-si (KR); Jun Soo Chang, Icheon-si (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Icheon-si (KR)

(21) Appl. No.: 11/759,930

(22) Filed: Jun. 7, 2007

(30) Foreign Application Priority Data
Dec. 28, 2006 (KR) 10-2006-0137221

(51) Int. Cl. H01L 21/336

(52) U.S. Cl. 438/270; 257/E21.41

(57) ABSTRACT

A method for fabricating a semiconductor device having a bulb-type recessed channel including forming a mask layer on the semiconductor substrate to expose a region where a trench for a bulb-type recessed channel can be formed, forming the trench in the semiconductor substrate, implanting dopant ions in three-dimensional radial directions with a predetermined tilt angle in the exposed region of the semiconductor substrate, removing the mask layer, forming a gate stack in the region including the trench, and forming a source/drain in the semiconductor substrate.

### CROSS-REFERENCE TO RELATED APPLICATION

The present application claims priority to Korean patent application number 10-2006-0137221, filed on Dec. 28, 2006, which is incorporated by reference in its entirety.

### BACKGROUND OF THE INVENTION

1. Field of the Invention

The invention relates to a method for fabricating a semiconductor device, and more particularly to a method for fabricating a semiconductor device equipped with a transistor having a bulb-type recessed channel.

2. Description of Related Technology

With a recent drastic decrease in the design rules for integrated circuit semiconductor devices, there has been difficulty in ensuring stable operation of transistors. For example, the channel length of transistors has markedly decreased due to a decrease in the gate width. Under such circumstances, the short channel effect, which induces a reduction in the threshold voltage, an increase in the leakage current, and deterioration in the refresh property, is generated frequently.

Such short channel effect causes serious generation of a punch-through between the source and drain of the transistor. The punch-through is recognized as a main factor for causing malfunction of a semiconductor device. In order to overcome this problem, a method of increasing an ion implantation dose so as to control the threshold voltage can be considered. However, this may induce write recovery time (TWR) defect instead by increasing channel resistance, and thereby deteriorate the refresh property of a device.

In order to overcome the short channel effect and ensure the stable operation of devices, a great deal of research has been conducted on methods for ensuring a longer channel length without any increase in design rules. Particularly, structures that have an extended channel length while maintaining a limited gate line width, for example, transistor structures having a bulb-type recessed channel manufactured using two step etching processes have been suggested.

Since transistors having a bulb-type recessed channel include channels along a bulb-type trench, the active channel length is increased compared with a conventional transistor having a planar channel. Therefore, the cell threshold voltage is increased, leakage current is decreased due to a decrease in the electric field, and the refresh property is improved. However, ensuring and improving the refresh property to increase the margin on the TWR defect as a result of continuous decrease in the size of devices remains a problem to be solved for the high-performance operation of highly integrated memory devices.

### BRIEF SUMMARY OF THE INVENTION

The invention relates to an ion implantation method for controlling the threshold voltage.

In accordance with one aspect of the invention, a method for fabricating a semiconductor device having a bulb-type recessed channel comprises forming a mask layer on a semiconductor substrate to expose a region where a trench for a bulb-type recessed channel can be formed, forming the trench in the semiconductor substrate, implanting dopant ions in three-dimensional radial directions with a predetermined tilt angle in the exposed region of the semiconductor substrate, removing the mask layer, forming a gate stack in the region including the trench, and forming a source/drain in the semiconductor substrate.

When implanting dopant ions in the semiconductor substrate, the ion implantation may be performed in two or more directions with a tilt angle in an X-axis or Y-axis direction relative to the semiconductor substrate. Herein, the ion implantation may be performed by equally dividing the total dose for each tilt angle. For example, it may be performed by having a tilt angle of −7°, 0°, and 7° relative to the X-axis and/or Y-axis, and the dose of 1×10¹² ion/cm² for each tilt angle.

When implanting dopant ions in the semiconductor substrate, the ion implantation may be performed in two directions with the tilt angle in the X-axis direction excluding 0° while the angle in the Y-axis direction is fixed. Alternatively, the ion implantation may be performed in three or more directions with the tilt angle in the X-axis direction including 0° while the angle in the Y-axis direction is fixed.

Furthermore, the ion implantation may be performed in two directions with the tilt angle in the Y-axis direction excluding 0° while the angle in the X-axis direction is fixed. Alternatively, the ion implantation may be performed in three or more directions with the tilt angle in the Y-axis direction including 0° while the angle in the X-axis direction is fixed.

### BRIEF DESCRIPTION OF THE DRAWINGS

The above and other aspects, features and other advantages of the invention will be more clearly understood from the following detailed description taken in conjunction with the accompanying drawings, in which:

FIGS. 1 to 5 are sectional views illustrating a method for fabricating a semiconductor device having bulk-type recessed channels according to an embodiment of the invention.

### DETAILED DESCRIPTION OF THE INVENTION

The invention provides a method for fabricating a semiconductor device which can increase the margin on the TWR defect or fail, which is a result of decreasing the size of the device, and improving the refresh property by improving the method of ion implantation for controlling the threshold voltage.

In general, the ion implantation for controlling the threshold voltage is performed to ensure a desired threshold voltage (Vt) when fabricating a MOS transistor. For example, in the case of an NMOS transistor, the ion implantation for controlling the threshold voltage is conducted by using a p-type dopant. Conventionally, during the ion implantation for controlling the threshold voltage, a dopant is implanted into a semiconductor substrate only in a direction perpendicular to the semiconductor substrate. Thus, the increase in the channel length is not big. However, in the invention, the ion implantation is performed in three-dimensional radial directions along a bulb-type trench during the ion implantation for controlling the threshold voltage. As a result, an active channel length between the source and drain of a transistor can be increased, and accordingly the threshold voltage of the transistor can be increased.

In general, if increasing the threshold voltage with a fixed dose is possible, the problem of deterioration in resistance capacitance (RC) characteristics caused by an increase in the dose for ion implantation for controlling the threshold voltage is prevented thereby improving the TWR fail. Meanwhile, the ion implantation dose can be decreased in the case of having a fixed value of the threshold voltage. Thereby, the contact resistance can be improved, and the refresh property can be improved by reducing the electric field in the junction.

FIGS. 1 to 5 are sectional views illustrating a method for fabricating a semiconductor device having bulk-type recessed channels according to an embodiment of the invention.

Referring to FIG. 1, a device isolation layer 102 defining an active region and an inactive region is formed on a semiconductor substrate 100. More specifically, a pad oxide layer (not shown) and a nitride layer (not shown) for exposing the semiconductor substrate 100 in the inactive region are formed on the semiconductor substrate 100. The exposed semiconductor substrate 100 is etched to a predetermined depth to form a trench. The trench is evenly buried using an insulating layer to form the device isolation layer 102. The pad oxide layer and nitride layer are then removed.

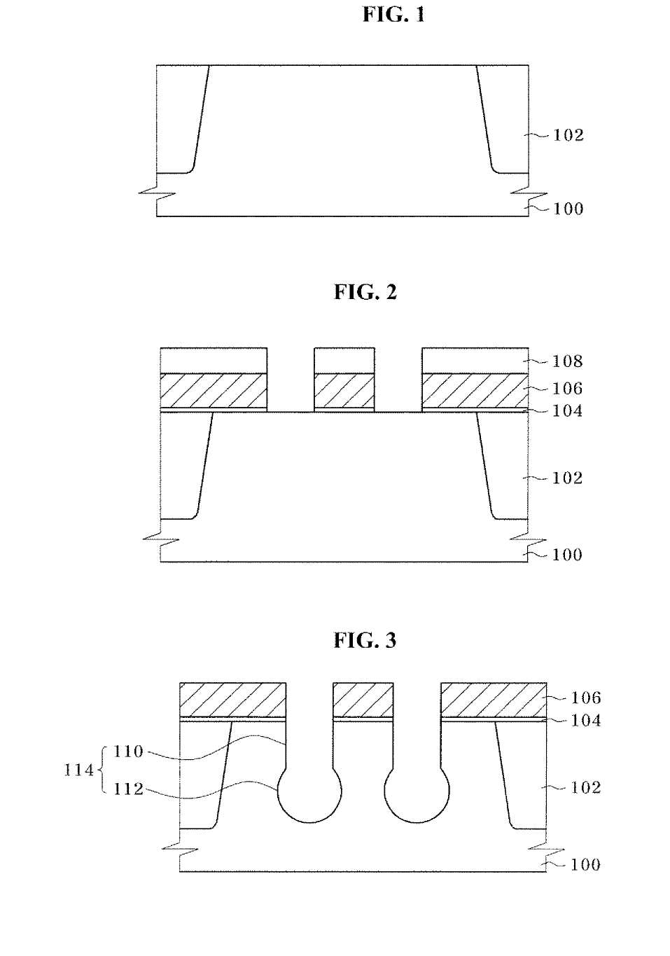

Referring to FIG. 2, a buffer oxide 104 and a hard mask layer 106 are formed on the semiconductor substrate 100. On this hard mask layer 106, a photoresist pattern 108, through which a region to form a gate is exposed, is formed. The hard mask layer 106 and the buffer oxide 104 are etched sequentially using the photoresist pattern 108 as an etching mask. As a result, the semiconductor substrate, in the region where a recessed gate is to be formed, is exposed.

The photoresist pattern 108 can be formed including an anti-reflection layer. The hard mask layer 106 is made of one or more layers selected from polysilicon layers, oxide layers, nitride layers, and metal layers. The hard mask layer 106 plays a role as an etching mask in the subsequent etching process on the semiconductor substrate 100 to form a bulb-type trench. Moreover, the hard mask layer 106 also plays a role as an ion implantation mask for preventing a dopant from implanting on the regions other than the channel region in the ion implanting process to form a channel. Therefore, the hard mask layer 106 has a thickness of 500 Å or more, and preferably about 500 Å to about 1000 Å.

Referring to FIG. 3, after removing the photoresist pattern 108, a first etching process is performed on the semiconductor substrate using the hard mask layer 106 as an etching mask to form a first trench 110 on the semiconductor substrate 100 with a predetermined depth. The first trench 110 is the neck portion of a trench for a bulb-type recessed channel.

Isotropic etching is performed on the bottom surface of the first trench using the hard mask layer 106 as an etching mask to form a second spherical trench 112 on the lower portion of the first trench 110. As a result, a trench 114 having a bulb-type recessed channel consisting of the first trench 110 and the second spherical trench 112 is formed.

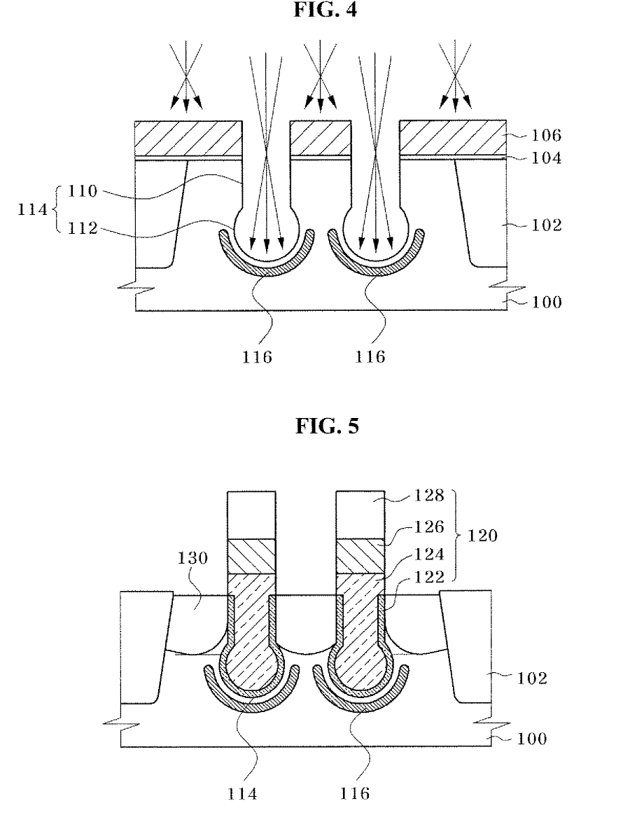

Referring to FIG. 4, the dopant ions are implanted for controlling the threshold voltage to the semiconductor substrate 100 using the hard mask layer 106 as an ion implantation mask. Herein, the ion implantation is performed in three-dimensions by varying the ion implantation tilt angle. That is, the dopant ions are implanted in radial directions as illustrated in FIG. 4. As a result, an ion implantation layer 116 is formed along the second spherical trench 112 and the an ion implantation layer 116 is necessarily different from a conventional one where ion implantation is only performed in the perpendicular direction with respect to the semiconductor substrate. When a heat treatment is subsequently performed, the implanted dopant is diffused and a channel is formed along the second spherical trench 112. Thus, the active channel length can be increased. That is, the threshold voltage can be increased without changing the ion implantation dose. Moreover, in the case where a fixed threshold voltage is to be realized, it can be realized with a reduced dose such that the refresh property is improved from a decrease in the contact resistance and in the electric field. Since the ion implantation process is performed after the hard mask layer 106 has been formed, the ion is not implanted in the region where a source/drain is to be formed because of the hard mask layer 106. Therefore, RC characteristics can be improved due to decrease of the electric field in the junction and decrease in the contact resistance.

The ion implantation for controlling the threshold voltage is performed by varying the ion implanting angle as illustrated in FIG. 4.

At this time, the total dose of the implanted dopant can be divided for each ion implantation direction. For example, when implanting the total dose of 3×10¹² ion/cm² in three directions corresponding to −7°, 0°, and 7°, ⅓ of the total dose, that is 1×10¹² ion/cm² can be implanted at each direction.

The ion implantation may be performed by continuously varying the ion implantation angle in-situ while maintaining the conditions, for example, the implantation energy, the dose, or the type of dopant, and the ion beam condition except for the ion implantation angle during the ion implantation. For example, after performing the ion implantation in the −7° direction, the ions are implanted in the 0° direction while maintaining the same implantation conditions and the same ion beam state, and then the ions may be implanted again in the 7° direction while maintaining the same implantation conditions and the same ion beam state.

The ion implantation can be performed by implementing a variety of implantation angles during the ion implantation for controlling the threshold voltage.

For example, the ion implantation is performed in two directions with a tilt angle in the X-axis direction excluding 0°, under the condition in which shadowing is not generated on the bottom portion of the trench during ion implantation according to the etching height of the trench 114 for a bulb-type recessed channel. That is, ions are implanted in two directions corresponding to a first direction of −20° to −1° and a second direction of 1° to 20°. The ion implantation may be performed by implanting the ions at an implantation angle and a particular dose. Alternatively, the ion implantation may be performed by implanting at an ion implantation angle and a particular dose while including 0° such that a first direction is −20° to −1°, a second direction is 0°, and a third direction is 1° to 20°. At this time, the angle in the Y-axis direction is fixed.

Furthermore, the ion implantation is performed in two directions with the tilt angle in the Y-axis direction excluding 0°, under the condition in which shadowing is not generated on the bottom portion of the trench. That is, ions are implanted in two directions corresponding to a first direction of −20° to −1° and a second direction of 1° to 20°. The ion implantation may be performed by implanting the ions at an implantation angle and a particular dose. Alternatively, the ion implantation may be performed by implanting at an ion implantation angle and a particular dose while including 0° such that a first direction is −20° to −1°, a second direction is 0°, and a third direction is 1° to 20°. At this time, the angle in the X-axis direction is fixed.

In another implantation method, the ion implantation may be performed by using three directions or more, e.g., four directions, five directions or even more with the tilt angle in the X-axis direction or Y-axis direction including 0°. At this time, the remaining angle in the Y-axis direction or X-axis direction is fixed for each tilt angle.

Another method for controlling the ion implantation angle can be performed by implanting at an the ion implantation angle and a particular dose while varying the tilt angle in the k-axis direction and Y-axis direction together when ion implanting in radial directions.

The above-mentioned ion implantation in three-dimensional radial directions can be adopted to field stop ion implantation process, the ion implantation process for preventing punch-through in addition to ion implantation process for controlling the threshold voltage.

Referring to FIG. 5, the hard mask layer 106 and the buffer oxide layer 104 are removed. In the region including the trench 114 for a bulb-type recessed channel, a gate stack 120 is formed and a source/drain 130 is formed by implanting a dopant. The gate stack 120 may be formed by including a gate insulating layer 122 formed along the inner wall of the trench, and a gate conducting layer 124, a metal layer 126, and a hard mask layer 128 laminated on the gate insulating layer 122.

According to the method for fabricating a semiconductor device having a bulb-type recessed channel of the invention, the dopant ion implantation for control of channel threshold voltage is performed in three-dimensional radial directions by varying the ion implantation angle. Then, a channel is formed along the spherical trench thereby increasing the active channel length. Therefore, the threshold voltage can be increased without changing the ion implantation dose. In the case where a fixed threshold voltage is to be realized, it can be realized with a reduced dose such that the refresh property is improved from a decrease in the contact resistance and in the electric field. Furthermore, the RC characteristics can be improved due to a decrease of the electric field in the junction and a decrease in the contact resistance.

The embodiments of the invention have been disclosed above for illustrative purposes. Those skilled in the art will appreciate that various modifications, additions and substitutions are possible, without departing from the scope and spirit of the invention as set forth in the accompanying claims.

What is claimed is:

1. A method for fabricating a semiconductor device having a bulb-type recessed channel comprising:
forming a mask layer on the semiconductor substrate to expose a region where a trench for a bulb-type recessed channel can be formed;
forming the trench in the semiconductor substrate;
implanting dopant ions in three-dimensional radial directions with a predetermined tilt angle in the exposed region of the semiconductor substrate;
removing the mask layer;
forming a gate stack in the region including the trench; and
forming a source/drain in the semiconductor substrate.

2. The method according to claim 1, wherein the mask layer has a laminated structure of one or more layers selected from the group consisting of polysilicon films, oxide films, nitride films, and metal films.

3. The method according to claim 1, wherein the mask layer has a thickness of about 500 Å to about 1,000 Å.

4. The method according to claim 1 comprising performing the ion implantation in two or more directions with the tilt angle in an X-axis or Y-axis direction relative to the semiconductor substrate.

5. The method according to claim 4, comprising performing the ion implantation along each tilt angle in an amount equal to the total dose divided by the number of tilt angles.

6. The method according to claim 4, comprising performing the ion implantation with the tilt angles of −7°, 0°, and 7°, and the dose of 1×10¹² ion/cm² for each tilt angle.

7. The method according to claim 4, comprising performing the ion implantation in-situ by varying the tilt angle while maintaining the conditions except for the tilt angle.

8. The method according to claim 4, comprising performing the ion implantation in two directions with the tilt angle in the X-axis direction excluding 0° while the angle in the Y-axis direction is fixed.

9. The method according to claim 4, comprising performing the ion implantation in two directions with the tilt angle in the Y-axis direction excluding 0° while the angle in the N-axis direction is fixed.

10. The method according to claim 4, comprising performing the ion implantation in three or more directions with the tilt angle in the X-axis direction including 0° while the angle in the Y-axis direction is fixed.

11. The method according to claim 4, comprising performing the ion implantation in three or more directions with the tilt angle in the Y-axis direction including 0° while the angle in the X-axis direction is fixed.
